(19) United States
(12) Patent Application Publication
(10) Pub. No.: US 2024/0324226 A1
(43) Pub. Date: Sep. 26, 2024

(54) SEMICONDUCTOR MEMORY DEVICE

(71) Applicant: Kioxia Corporation, Tokyo (JP)

(72) Inventor: Shoichi MIYAZAKI, Yokkaichi Mie (JP)

(73) Assignee: Kioxia Corporation, Tokyo (JP)

(21) Appl. No.: 18/591,886

(22) Filed: Feb. 29, 2024

(30) Foreign Application Priority Data
Mar. 22, 2023 (JP) 2023-045570

(51) Int. Cl. H10B 43/35; G11C 16/04; H01L 23/528; H10B 41/10; H10B 41/27; H10B 41/35; H10B 43/10; H10B 43/27

(52) U.S. Cl. CPC H10B 43/35; G11C 16/0483; H01L 23/5283; H10B 41/10; H10B 41/27; H10B 41/35; H10B 43/10; H10B 43/27

(57) ABSTRACT

A memory device includes a stacked body including electrode layers and insulating layers; columnar bodies extending through the stacked body; and a contact coupled to a first electrode layer and passing through one or more second electrode layers, the first electrode layer including a first surface and a second surface, the first surface disposed farther away from the second electrode layers than the second surface. The contact includes a first insulating film, a second insulating film, and a metal film. A first end portion of the first insulating film protrudes into the first electrode layer through the second surface. A second end portion of the second insulating film is in contact with a portion of the second surface. A distance t1 between the first end portion and the first surface is shorter than a distance t2 between the second end portion and the first surface.

### CROSS-REFERENCE TO RELATED APPLICATION

This application is based upon and claims the benefit of priority from Japanese Patent Application No. 2023-045570, filed Mar. 22, 2023, the entire contents of which are incorporated herein by reference.

### FIELD

Embodiments described herein relate generally to a semiconductor memory device.

### BACKGROUND

A NAND flash memory in which memory cells are arranged three-dimensionally is known.

### DESCRIPTION OF THE DRAWINGS

FIG. 1 is a block diagram illustrating a part of a configuration of a semiconductor memory device according to a first embodiment.

FIG. 2 is a diagram illustrating an equivalent circuit of a part of a memory cell array of the first embodiment.

FIG. 3 is a cross-sectional view illustrating a part of a semiconductor memory device according to the first embodiment.

FIG. 4 is an enlarged cross-sectional view of a region surrounded by line F4 of the semiconductor memory device illustrated in FIG. 3.

FIG. 5 is a cross-sectional view taken along line F5-F5 of the semiconductor memory device illustrated in FIG. 4.

FIG. 6 is a cross-sectional view taken along line F6-F6 of the semiconductor memory device illustrated in FIG. 3.

FIG. 7 is a cross-sectional view taken along line F8-F8 of the semiconductor memory device illustrated in FIG. 3.

FIG. 8 is a view illustrating an arrangement relationship between contacts and conductive layers in a connection region IR.

FIG. 9 is an enlarged cross-sectional view illustrating a region surrounded by line F9 of the semiconductor memory device illustrated in FIG. 3.

FIGS. 10A to 10C are cross-sectional views illustrating a method of manufacturing a semiconductor memory device of the first embodiment.

FIGS. 11A to 11C are cross-sectional views illustrating the method of manufacturing the semiconductor memory device of the first embodiment.

### DETAILED DESCRIPTION

Embodiments provide a semiconductor memory device of which electrical characteristics can be improved.

In general, according to one embodiment, a semiconductor memory device includes a substrate; a stacked body provided above the substrate and including a plurality of electrode layers and a plurality of insulating layers alternately stacked on top of one another in a first direction; a plurality of columnar bodies extending through the stacked body in the first direction; and a contact electrically coupled to a first electrode layer of the plurality of electrode layers, extending in the first direction, and passing through one or more second electrode layers of the plurality of electrode layers, the first electrode layer including a first surface and a second surface opposite to each other, the first surface disposed farther away from the one or more second electrode layers than the second surface in the first direction. The contact includes a first insulating film, a second insulating film, and a metal film all extending in the first direction, and wherein the first insulating film, the second insulating film, and the metal film are sequentially arranged from an outer side of the contact to an inner side of the contact. A first end portion of the first insulating film protrudes into the first electrode layer through the second surface in the first direction. A second end portion of the second insulating film is in contact with at least a portion of the second surface of the first electrode layer. A distance t1 between the first end portion of the first insulating film and the first surface of the first electrode layer is shorter than a distance t2 between the second end portion of the second insulating film and the first surface of the first electrode layer.

Hereinafter, a semiconductor memory device of an embodiment will be described with reference to the drawings. In the following description, configurations having the same or similar functions are designated by the same reference numerals. Redundant descriptions of the configurations may be omitted. In the following description, when reference numerals that end with numbers or letters for distinction do not need to be distinguished from each other, trailing numbers or letters may be omitted.

Terms are defined as follows in the present application. “Parallel”, “orthogonal”, or “same” may respectively include “substantially parallel”, “substantially orthogonal”, or “substantially the same”. A term “connection” is not limited to mechanical connection and may include electrical connection. That is, the term “connection” is not limited to a case where a plurality of elements are directly connected, and may include a case where a plurality of elements are connected with another element interposed therebetween. “Overlapping” is not limited to a case where a plurality of elements are in contact with each other, and may also include a case where a plurality of elements are separated from each other (a case where projected images of a plurality of elements overlap each other when viewed from a certain direction).

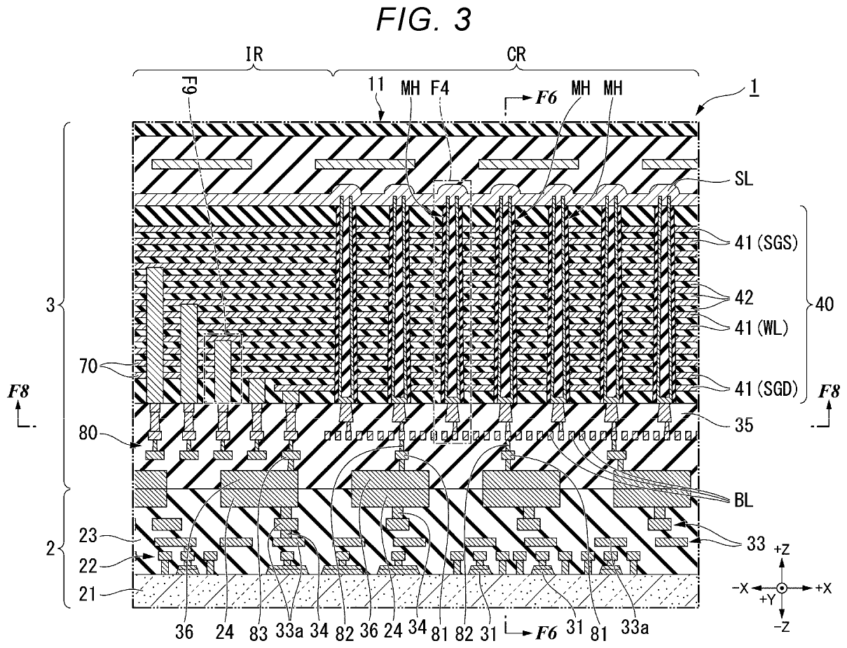

+X direction, −X direction, +Y direction, −Y direction, +Z direction, and −Z direction are defined as follows. The +X direction is a direction in which a word line WL to be described below extends (see FIG. 3). The −X direction is opposite to the +X direction. When the +X direction and the −X direction are not distinguished from each other, both directions are simply referred to as an “X direction”. The +Y direction intersects (for example, is orthogonal to) the X direction. The +Y direction is a direction in which a bit line BL to be described below extends. The −Y direction is opposite to the +Y direction. When the +Y direction and the −Y direction are not distinguished from each other, both directions are simply referred to as a “Y direction”. The +Z direction intersects (for example, is orthogonal to) the X direction and the Y direction. The +Z direction is a direction from a semiconductor substrate 21 toward a stacked body 40 (see FIG. 3). The −Z direction is opposite to the +Z direction. When the +Z direction and the −Z direction are not distinguished from each other, both directions are simply referred to as a “Z direction”.

In the following description, the +Z direction side may be referred to as “upper” and the −Z direction side may be referred to as “lower”. Also, in the following description, a position in the Z direction may be referred to as a “height”. Here, these expressions are for convenience only and do not define a direction of gravity. The Z direction is an example of a “first direction”. The X direction is an example of a “second direction”. The Y direction is an example of a “third direction”. In the drawings to be described below, illustrations of configurations not related to the descriptions may be omitted.

### First Embodiment

### 1. Configuration of Semiconductor Memory Device

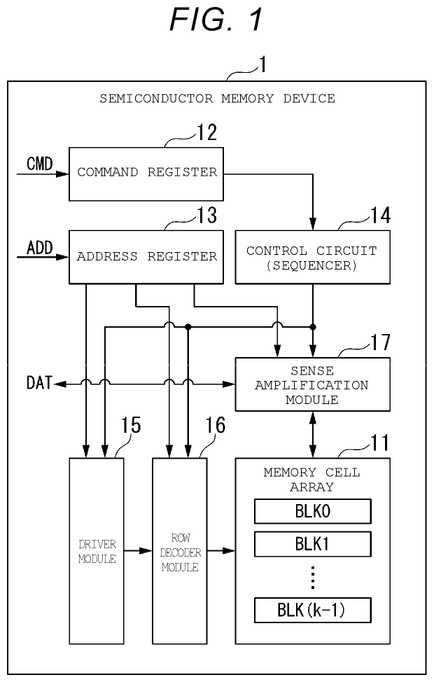

FIG. 1 is a block diagram illustrating a part of a configuration of a semiconductor memory device 1. The semiconductor memory device 1 is, for example, a non-volatile semiconductor memory device, and is a NAND flash memory. The semiconductor memory device 1 can be connected to, for example, an external host device and used as a storage space of a host device. The semiconductor memory device 1 includes, for example, a memory cell array 11, a command register 12, an address register 13, a control circuit (sequencer) 14, a driver module 15, a row decoder module 16, and a sense amplification module 17.

The memory cell array 11 includes a plurality of blocks BLK0 to BLK (k−1) (where k is an integer of 1 or more). The block BLK is a collection of memory cell transistors. The block BLK is used as, for example, a data erasing unit. The memory cell array 11 is provided with a plurality of bit lines and a plurality of word lines. Each memory cell transistor is associated with one bit line and one word line.

The command register 12 stores a command CMD that the semiconductor memory device 1 receives from a host device. The address register 13 stores address information ADD that the semiconductor memory device 1 receives from the host device. The address information ADD is used to select the blocks BLK, word lines, and bit lines. The control circuit 14 controls various operations of the semiconductor memory device 1. For example, the control circuit 14 performs a data write operation, a read operation, or an erasing operation based on the command CMD stored in the command register 12.

The driver module 15 includes a voltage generation circuit and generates voltages used for various operations of the semiconductor memory device 1. The row decoder module 16 transmits a voltage applied to a signal line corresponding to a selected word line to the selected word line. The sense amplification module 17 applies a desired voltage to each bit line in a write operation. In a read operation, the sense amplification module 17 determines a data value stored in each memory cell transistor based on a voltage of each bit line, and transmits the determination result as read data DAT to the host device.

### 2. Electrical Configuration of Memory Cell Array

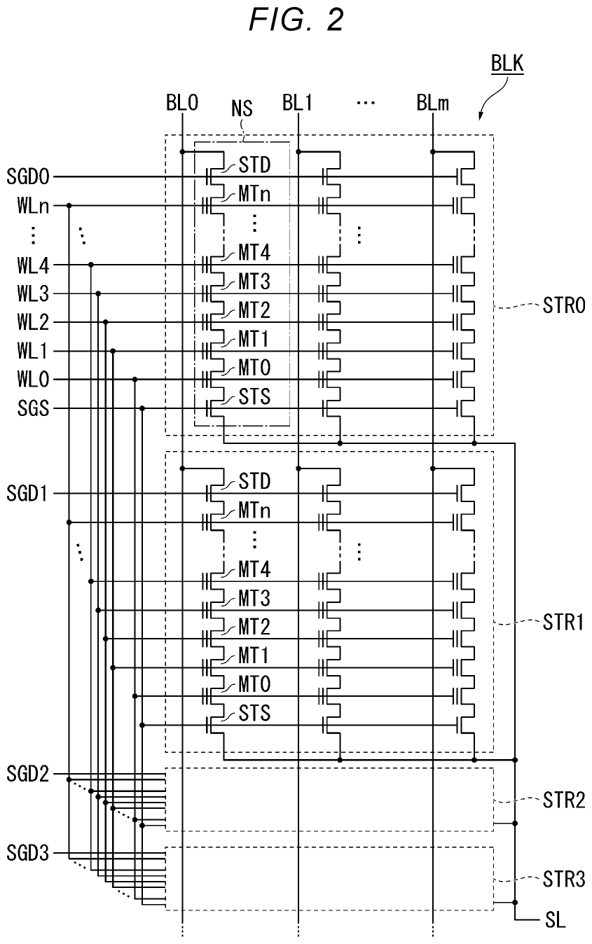

FIG. 2 is a diagram illustrating an equivalent circuit of a part of the memory cell array 11. FIG. 2 illustrates one block BLK provided in the memory cell array 11. The block BLK includes a plurality of (for example, four) strings STR0 to STR3.

Each string STR includes a plurality of NAND strings NS associated with bit lines BL0 to BLm (m is an integer greater than or equal to 1). Each NAND string NS includes, for example, a plurality of memory cell transistors MT0 to MTn (where n is an integer of 1 or more), at least one drain-side select transistor STD, and at least one source-side select transistor STS.

In each NAND string NS, the memory cell transistors MT0 to MTn are connected in series to each other. Each memory cell transistor MT includes a control gate and a charge accumulation portion. The control gate of the memory cell transistor MT is connected to any one of the word lines WL0 to WLn. In each memory cell transistor MT, electric charges are accumulated in the charge accumulation portion according to a voltage applied to the control gate via the word line WL, and a data value is stored in a non-volatile manner.

A drain of the drain-side select transistor STD is connected to the bit line BL corresponding to the corresponding NAND string NS. A source of the drain-side select transistor STD is connected to one end of the memory cell transistors MT0 to MTn connected in series to each other. A control gate of the drain-side select transistor STD is connected to one of the drain-side select gate lines SGD0 to SGD3. The drain-side select transistor STD is electrically connected to the row decoder module 16 via the drain-side select gate line SGD. The drain-side select transistor STD connects the NAND string NS to the bit line BL when a predetermined voltage is applied to the corresponding drain-side select gate line SGD.

A drain of the source-side select transistor STS is connected to the other end of one of the memory cell transistors MT0 to MTn connected in series to each other. A source of the source-side select transistor STS is connected to a source line SL. A control gate of the source-side select transistor STS is connected to a source-side select gate line SGS. The source-side select transistor STS connects the NAND string NS to the source line SL when a predetermined voltage is applied to the source-side select gate line SGS.

In the same block BLK, control gates of the memory cell transistors MT0 to MTn are respectively and commonly connected to the corresponding word lines WL0 to WLn. In the same string STR, control gates of the drain-side select transistors STD are commonly connected to the corresponding drain-side select gate lines SGD0 to SGD3. The control gate of the source-side select transistors STS are commonly connected to the source-side select gate line SGS. In the memory cell array 11, the bit line BL is shared by the NAND strings NS to which the same column address is assigned in the plurality of strings STR.

### 3. Physical Configuration of Semiconductor Memory Device

Next, a physical configuration of the semiconductor memory device 1 will be described.

FIG. 3 is a cross-sectional view illustrating a part of the semiconductor memory device 1. The semiconductor memory device 1 includes, for example, a first chip 2 and a second chip 3.

### 3.1 First Chip

The first chip 2 is a circuit chip including a peripheral circuit. The first chip 2 includes, for example, the semiconductor substrate 21, a peripheral circuit 22, an insulating portion 23, and a plurality of pads 24.

The semiconductor substrate 1 is, for example, a substrate that is a base of the first chip 2. At least a part of the semiconductor substrate 21 has a plate shape extending in the X direction and the Y direction. The semiconductor substrate 21 is formed of a semiconductor material such as silicon.

The semiconductor substrate 21 is divided into a cell region CR in which a memory pillar MH to be described below is disposed, and a connection region IR disposed adjacent to the cell region CR for applying a voltage to the word line WL corresponding to the memory cell transistor MT. Details of each region are described below.

The peripheral circuit 22 is a circuit for functioning the memory cell array 11 described above. The peripheral circuit 22 includes one or more of the command register 12, the address register 13, the control circuit 14, the driver module 15, the row decoder module 16, and the sense amplification module 17 described above. The peripheral circuit 22 includes, for example, a plurality of transistors 31, a plurality of wiring layers 33, and a plurality of vias 34.

Transistors 31 are provided on the semiconductor substrate 21. The plurality of wiring layers 33 are disposed at a plurality of heights. Each wiring layer 33 includes a plurality of wires 33a extending in the X direction or the Y direction. Vias 34 are electrical connection portions extending in the Z direction in the first chip 2. The plurality of vias 34 include, for example, the via 34 that connects two wires 33a disposed at different heights to each other, and the via 34 that connects the wire 33a to a pad 24.

An insulating portion 23 covers the plurality of transistors 31, the plurality of wiring layers 33, and the plurality of vias 34. The plurality of pads 24 are provided on a surface of the insulating portion 23. Each pad 24 is electrically connected to the wire 33a through the via 34.

### 3.2 Second Chip

The second chip 3 is an array chip that includes the memory cell array 11. The second chip 3 includes, for example, the memory cell array 11, an insulating portion 35, and a plurality of pads 36. Here, the insulating portion 35 and the plurality of pads 36 are described, and the memory cell array 11 is described below.

The insulating portion 35 covers the memory cell array 11. The plurality of pads 36 are provided on a surface of the insulating portion 35. Each pad 36 is electrically connected to a wire (for example, a wire 81 or a wire 83) provided in a wiring portion 80 of the memory cell array 11 to be described below. In the present embodiment, the plurality of pads 24 of the first chip 2 and the plurality of pads 36 of the second chip 3 are bonded together to face each other, and accordingly, the first chip 2 and the second chip 3 are formed integrally.

Although FIG. 3 illustrates an example in which the second chip 3 that is an array chip is bonded to the first chip 2 that is a circuit chip (CBA: CMOS bonding array), the present embodiment is not limited thereto. For example, the peripheral circuit 22 may be located on a side (periphery) of the memory cell array 11 in the X direction or the Y direction. Further, for example, the peripheral circuit 22 may be disposed below the memory cell array 11 (CUA: CMOS under array).

### 4. Physical Configuration of Memory Cell Array

Next, a physical configuration of the memory cell array will be described.

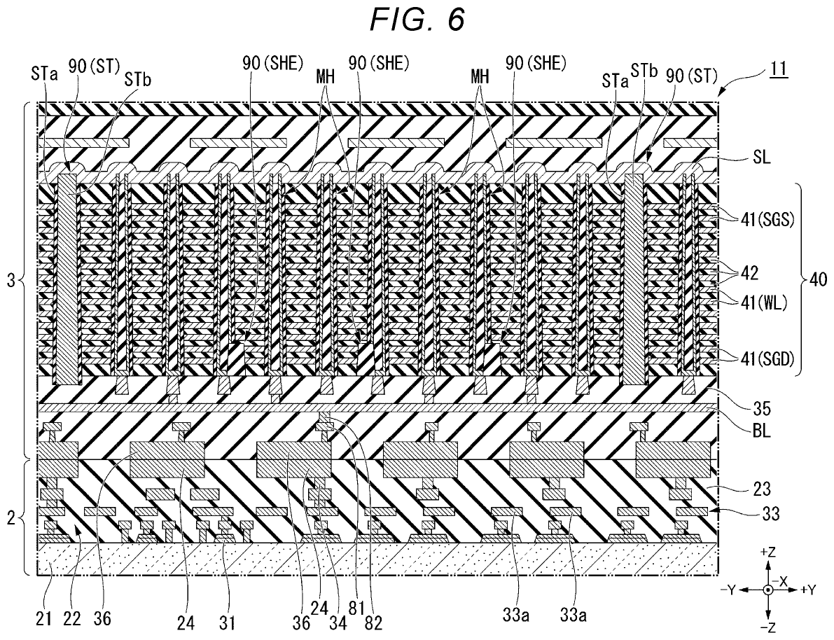

As illustrated in FIG. 3, the memory cell array 11 includes a stacked body 40, the source line SL, the plurality of memory pillars MH, the plurality of bit lines BL, a conductive layer contact 70, the wiring portion 80, and a plurality of division portions 90 (see FIG. 6).

### 4.1 Stacked Body

First, the stacked body 40 will be described.

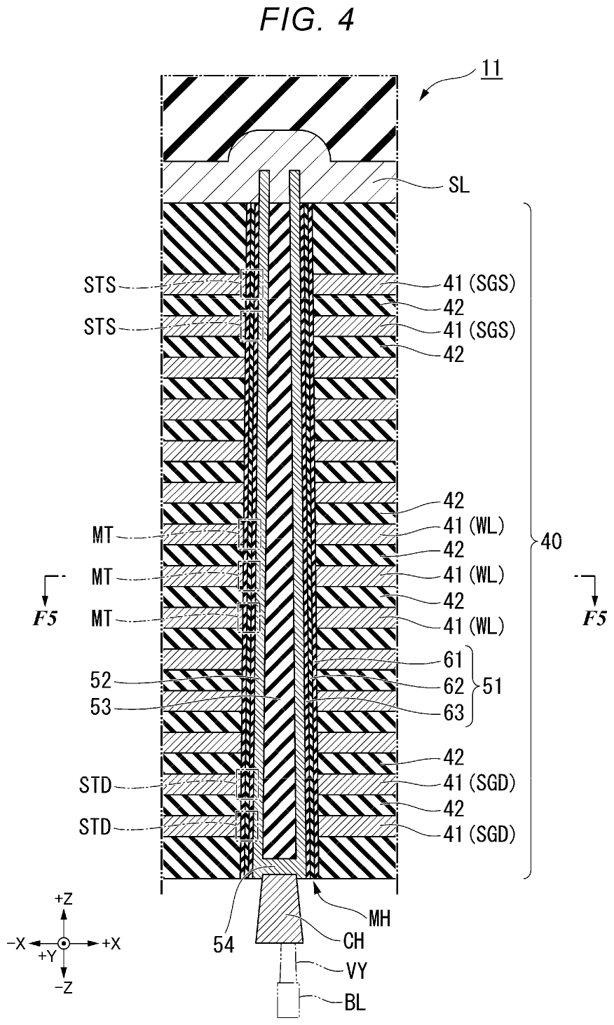

FIG. 4 is an enlarged cross-sectional view of a region surrounded by line F4 of the semiconductor memory device 1 illustrated in FIG. 3. The stacked body 40 includes a plurality of conductive layers 41 and a plurality of insulating layers 42. The plurality of conductive layers 41 and the plurality of insulating layers 42 are alternately stacked one by one in the Z direction.

The conductive layer 41 extends in the X direction and the Y direction. Each conductive layer 41 is formed of a conductive material such as tungsten or molybdenum. The conductive layer 41 is an example of a “gate electrode layer”.

One or more (for example, a plurality of) conductive layers 41 located below, among the plurality of conductive layers 41, function as the drain-side select gate lines SGD. The drain-side select gate line SGD is provided in common for the plurality of memory pillars MH arranged in the X direction or the Y direction. An intersection between the drain-side select gate line SGD and a channel layer 52 (described below) of each memory pillar MH functions as the above-described drain-side select transistor STD.

One or more (for example, a plurality of) conductive layers 41 located above, among the plurality of conductive layers 41, function as the source-side select gate lines SGS. The source-side select gate line SGS is provided in common for the plurality of memory pillars MH arranged in the X direction or the Y direction. An intersection between the source-side select gate line SGS and the channel layer 52 of each memory pillar MH functions as the above-described source-side select transistor STS.

Among the plurality of conductive layers 41, at least some of the remaining conductive layers 41 provided between the conductive layers 41 functioning as the drain-side select gate line SGD and the source-side select gate line SGS functions as the word lines WL. The word line WL is provided in common for a plurality of memory pillars MH arranged in the X direction and the Y direction. In the present embodiment, an intersection between the word line WL and the channel layer 52 of each memory pillar MH functions as the memory cell transistor MT. The memory cell transistor MT will be described below in detail.

An insulating layer 42 is an interlayer insulating film provided between two conductive layers 41 adjacent in the Z direction and insulating the corresponding two conductive layers 41. The insulating layer 42 extends in the X direction and the Y direction. The insulating layer 42 is formed of a film including, for example, silicon and oxygen.

### 4.2 Source Line

The source line SL is disposed above the stacked body 40. The source line SL is a conductive layer extending in the X direction and the Y direction. The source line SL is formed of a conductive material such as polysilicon or tungsten.

### 4.3 Memory Pillar

The plurality of memory pillars MH are arranged in the X direction and the Y direction (see FIG. 3). Each memory pillar MH extends in the Z direction in the stacked body 40 and passes through the stacked body 40. An upper end of the memory pillar MH is in contact with the source line SL. Meanwhile, a lower end of each memory pillar MH is in contact with the wiring portion 80. The memory pillar MH is an example of a “columnar body”.

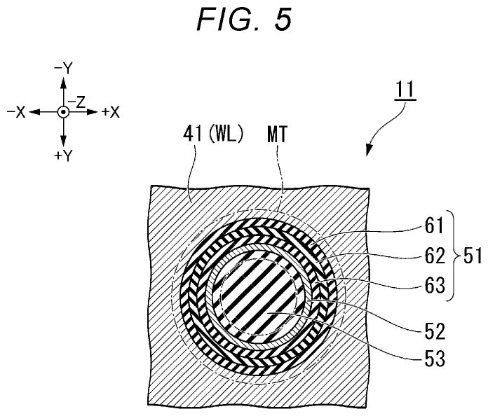

FIG. 5 is a cross-sectional view taken along line F5-F5 of the semiconductor memory device 1 illustrated in FIG. 4. The memory pillar MH includes, for example, a memory film (multilayer film) 51, the channel layer 52, an insulating core 53, and a cap portion 54 (see FIG. 4).

The memory film 51 is provided on an outer periphery side of the channel layer 52. The memory film 51 is placed between the plurality of conductive layers 41 and the channel layer 52. The memory film 51 includes, for example, a block insulating film 61, a charge trap film 62, and a tunnel insulating film 63.

The block insulating film 61 is provided between the plurality of conductive layers 41 and the charge trap film 62. The block insulating film 61 prevents back tunneling. The back tunneling is a phenomenon in which electric charges are injected from the word line WL to the charge trap film 62. The block insulating film 61 is formed in an annular shape and extends in the Z direction. For example, the block insulating film 61 extends over the entire length of the memory pillar MH in the Z direction. The block insulating film 61 is, for example, a stacked structural film in which a plurality of insulating films such as a film including silicon and oxygen or a film including metal and oxygen are stacked. An example of a film including metal and oxygen is aluminum oxide. The block insulating film 61 may include a high dielectric constant material (high-k material) such as silicon nitride or hafnium oxide.

The charge trap film 62 is placed between the block insulating film 61 and the tunnel insulating film 63. The charge trap film 62 is formed in an annular shape and extends in the Z direction. For example, the charge trap film 62 extends over the entire length of the memory pillar MH in the Z direction. The charge trap film 62 is a functional film that has many crystal defects (trap levels) and can trap electric charges in the crystal defects. The charge trap film 62 is formed of a film including, for example, silicon and nitrogen. A portion of the charge trap film 62 adjacent to each word line WL is an example of a “charge accumulation portion” capable of storing information by accumulating electric charges.

The tunnel insulating film 63 is provided between the channel layer 52 and the charge trap film 62. The tunnel insulating film 63 is formed in, for example, an annular shape along an outer peripheral surface of the channel layer 52 and extends in the Z direction along the channel layer 52. For example, the tunnel insulating film 63 extends over the entire length of the memory pillar MH in the Z direction. The tunnel insulating film 63 is a potential barrier between the channel layer 52 and the charge trap film 62. The tunnel insulating film 63 is formed of a film including silicon and oxygen, or a film including silicon, oxygen, and nitrogen.

Thereby, at the same height as each word line WL, a metal-Al-nitride-oxide-silicon (MANOS) type memory cell transistor MT is formed by an end portion of the word line WL adjacent to the memory pillar MH, the block insulating film 61, the charge trap film 62, the tunnel insulating film 63, and the channel layer 52. The memory film 51 may have a floating gate type charge accumulation portion (floating gate electrode) instead of the charge trap film 62, as a charge accumulation portion. The floating gate electrode is formed of, for example, polysilicon including impurities.

The insulating core 53 is provided inside the channel layer 52. The insulating core 53 fills at least a part of the inside of the channel layer 52. The insulating core 53 is formed of a film including silicon and oxygen. A part of the insulating core 53 may be formed in an annular shape along an inner peripheral surface of the channel layer 52 and have a space portion (air gap) therein. The insulating core 53 extends in the Z direction. For example, the insulating core 53 extends over most of the memory pillar MH in the Z direction except an upper end portion of the memory pillar MH (see FIG. 4).

Referring again to FIG. 4, the cap portion 54 is described. The cap portion 54 is provided below the insulating core 53. The cap portion 54 is a semiconductor portion formed of a semiconductor material such as amorphous silicon or polysilicon. The cap portion 54 may be doped with impurities. The cap portion 54 is disposed on an inner periphery side of a lower end portion of the memory film 51 and is formed integrally with the channel layer 52. The cap portion 54 forms a lower end portion of the memory pillar MH together with a lower end portion of the channel layer 52.

### 4.4 Bit Line

Next, returning to FIG. 3, the bit line BL is described.

The bit line BL is a wire for selecting one memory pillar MH from among the plurality of memory pillars MH. The plurality of bit lines BL are disposed on a lower side with respect to the stacked body 40. The plurality of bit lines BL are arranged in the X direction at intervals in the X direction. Each bit line BL extends in the Y direction. Each bit line BL extends below the plurality of corresponding memory pillars MH.

Each bit line BL overlaps the plurality of memory pillars MH when viewed from the Z direction (see FIG. 6). Each bit line BL is connected to the channel layer 52 of the memory pillar MH. Thereby, any memory cell transistor MT can be selected from among the plurality of memory cell transistors MT arranged three-dimensionally by combining the word lines WL and the bit lines BL.

### 4.5 Wiring Portion

Next, the wiring portion 80 will be described. The wiring portion 80 is disposed between, for example, the stacked body 40 and the semiconductor substrate 21. The wiring portion 80 includes, for example, a plurality of wires 81, a plurality of vias 82, and a plurality of wires 83.

The wire 81 is an electrical connection portion that electrically connects the bit line BL to the pad 36. For example, the plurality of wires 81 are disposed below the plurality of bit lines BL. For example, each wire 81 extends in the X direction or the Y direction. The via 82, which electrically connects the wire 81 to the bit line BL, is provided between the wire 81 and the bit line BL.

The wire 83 is an electrical connection portion that electrically connects the conductive layer contact 70 to the pad 36. The wire 83 is electrically connected to the conductive layer 41 via the conductive layer contact 70. A voltage is applied to the wire 83 to select the conductive layer 41 (the word line WL, the drain-side select gate line SGD, or the source-side select gate line SGS).

### 4.6 Conductive Layer Contact

As illustrated in FIG. 3, the conductive layer contact 70 is an electrical connection portion that electrically connects the conductive layer 41 to the wire 83 provided in the wiring portion 80. A plurality of contacts 70 extend in the Z direction and have, for example, different lengths in the Z direction. An upper end of each contact 70 is in contact with a corresponding conductive layer 41. The upper end of each contact 70 is electrically connected to the corresponding conductive layer 41.

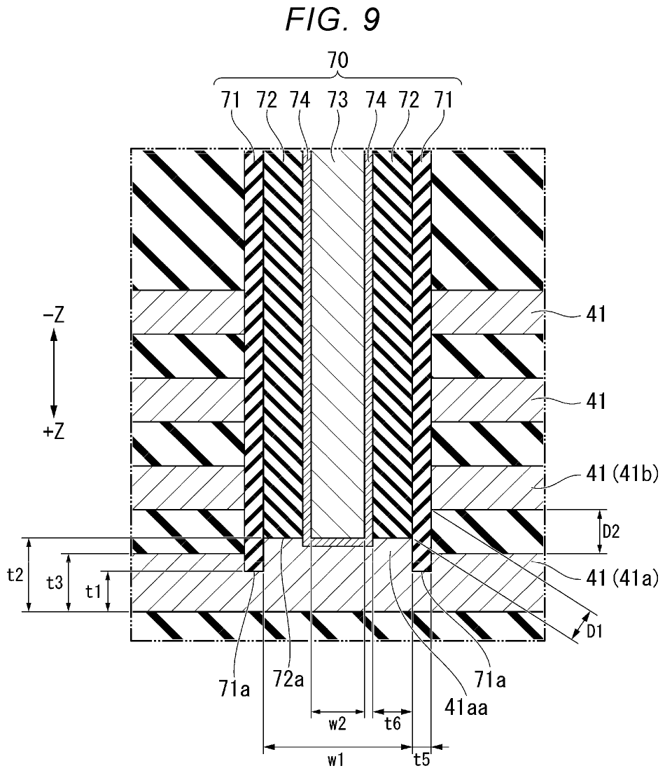

For example, the plurality of contacts 70 are disposed adjacent to a cell region CR, in which the memory pillar MH is disposed, in the memory cell array 11, and are disposed to correspond to the connection region IR for electrically connecting the wire 83 to the word line WL. The contact 70 passes through at least one of the conductive layers 41 in the connection region IR. For example, in the example of FIG. 9 to be described below, the contact 70 passes through a second conductive layer 41b. The detailed structure of the contact 70 and a connection structure of the contact 70 and the conductive layer 41 will be described below.

### 5. Division Portion of Stacked Body

Next, the division portion 90 will be described.

FIG. 6 is a cross-sectional view taken along line F6-F6 of the semiconductor memory device 1 illustrated in FIG. 3. In the present embodiment, a plurality of division portions 90 are provided in the stacked body 40. The plurality of division portions 90 are arranged separately in the Y direction. The plurality of division portions 90 each extend in the Z direction in the stacked body 40 and divide one or more conductive layers 41, which include the lowest layer among the plurality of conductive layers 41, in the Y direction. The plurality of division portions 90 include, for example, a plurality of division portions ST and a plurality of division portions SHE.

### 5.1 Division Portion ST

The division portion ST is a wall portion that divides the stacked body 40 in the Y direction. The plurality of division portions ST are arranged separately in the Y direction. The division portion ST extends in the Z direction, passes through the stacked body 40, and also extends in the X direction. That is, the division portion ST is a wall portion extending in the Z direction and the X direction. The division portion ST divides each of all conductive layers 41 provided in the stacked body 40 in the Y direction. The division portion ST includes, for example, an insulating portion STa and a conductive portion STb.

The insulating portion STa extends in the Z direction and passes through the stacked body 40. The insulating portion STa divides each of the plurality of conductive layers 41 provided in the stacked body 40 in the Y direction. The insulating portion STa is formed of a film including, for example, silicon and oxygen.

The conductive portion STb is provided inside the insulating portion STa. The conductive portion STb extends in the Z direction and passes through the stacked body 40. An upper end of conductive portion STb is in contact with the source line SL. The conductive portion STb is made of a conductive material such as tungsten or molybdenum. For example, the conductive portion STb is an electrical connection portion that connects the source line SL to a wire in the memory cell array 11.

### 5.2 Division Portion SHE

The division portion SHE is a shallower division portion in the Z direction than the division portion ST, and is a wall portion that divides a lower end portion of the stacked body 40 in the Y direction. The plurality of division portions SHE are arranged separately in the Y direction. In the present embodiment, a plurality of (for example, three) division portions SHE exist between two division portions ST adjacent to each other in the Y direction. The division portion SHE is provided at a lower end portion of the stacked body 40, extends halfway through the stacked body 40 in the Z direction, and also extends in the X direction. That is, the division portion SHE is a wall portion extending in the Z direction and the X direction.

The division portion SHE passes through some of the conductive layers 41 including the lowest layer among the plurality of conductive layers 41, and divides some conductive layers 41 in the Y direction. For example, the division portion SHE passes through each of all the conductive layers 41 functioning as the drain-side select gate line SGD. Meanwhile, the division portion SHE does not reach the conductive layer 41 functioning as the word line WL. The division portion SHE divides only the conductive layer 41 functioning as the drain-side select gate line SGD in the Y direction. The division portion SHE is formed of a film including, for example, silicon and oxygen.

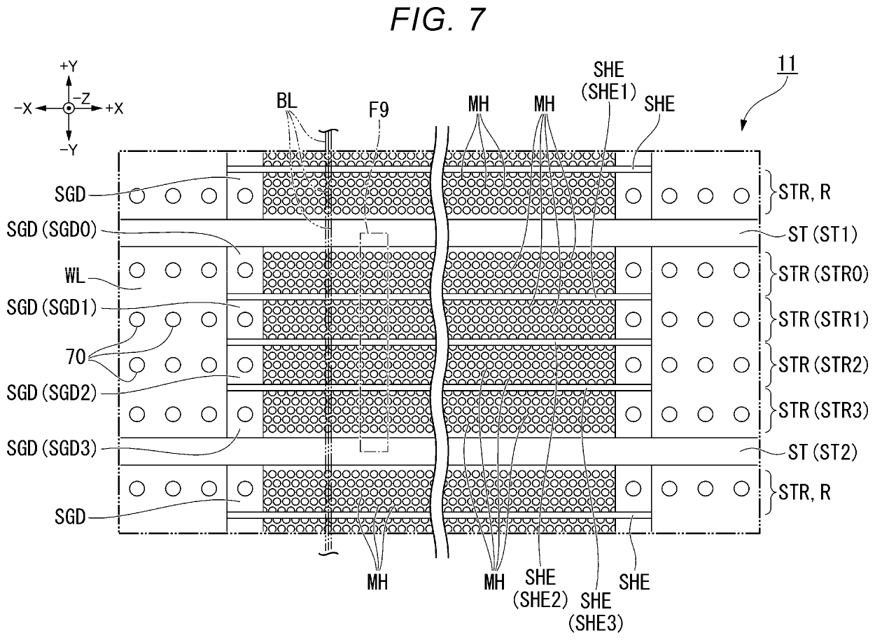

FIG. 7 is a cross-sectional view taken along line F8-F8 of the semiconductor memory device 1 illustrated in FIG. 3. In the present embodiment, the conductive layer 41 corresponding to the drain-side select gate line SGD is divided in the Y direction by the division portion ST and the division portion SHE. Thereby, a drain-side select gate line SGD extending in the X direction is formed. Thereby, a region divided by the division portion ST or the division portion SHE corresponds to one string STR.

In the present embodiment, three division portions SHE (division portions SHE1, SHE2, and SHE3) exist between two division portions ST (division portions ST1 and ST2) adjacent to each other in the Y direction. The division portion SHE1, the division portion SHE2, and the division portion SHE3 are arranged in this order from the division portion ST1 to the division portion ST2.

### 6. Contact and Connection Region of Conductive Layer

Next, a detailed structure of the contact 70 and a connection region between the contact 70 and the word line WL (conductive layer 41) will be described.

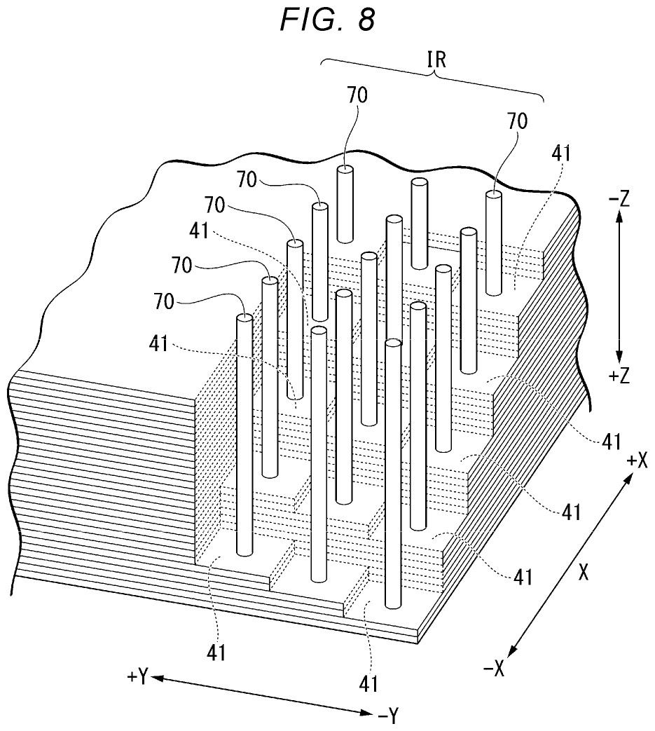

FIG. 8 is a view illustrating a connection region IR in which the contacts 70 are arranged together. Arranging the contacts 70 together is not always required, and the respective contacts 70 may be arranged to be dispersed. Since the connection region IR illustrated in FIG. 8 clearly shows an arrangement of connection portions of each contact 70 and the word line WL (conductive layer 41), illustration of all the word lines WL (conductive layers 41) in the −Z direction from the conductive layer 41 of a connection target among the word lines WL (conductive layers 41) around each contact 70 is omitted. Also, FIG. 9 is an enlarged cross-sectional view of a region surrounded by line F9 of the semiconductor memory device 1 illustrated in FIG. 3. In the connection region IR illustrated in FIG. 9, for the sake of convenience of description, the −Z direction is upward, and the +Z direction is downward.

In the example of FIG. 8, columns of contacts 70 arranged in the X direction are arranged in three columns in the Y direction. This structure will be appropriately referred to as a “three-column contact” hereinafter.

Among the contacts of three columns in FIG. 8, three contacts (contacts in the first row) located furthest in the +X direction are respectively connected to the first, second, and third (three) word lines WL (conductive layers 41) in the −Z direction. That is, the contacts 70 adjacent in the −Y direction to the contact 70 connected to the word line WL (the lowest word line WL in FIG. 3) located furthest in the −Z direction are connected to the word line WL (the second word line WL from the bottom) shifted by one layer in the +Z direction. The contacts 70 adjacent in the −Y direction to the contact 70 connected to the second word line WL from the bottom are connected to the word line WL (the third word line WL from the bottom) shifted by one layer in the +Z direction.

Three contacts 70 (contacts 70 in the second row) adjacent in the −X direction to the contact 70 in the first row are respectively connected to the fourth, fifth, and sixth (three) word lines WL in the −Z direction. That is, the contacts 70 adjacent in the −X direction to the contact 70 connected to the word line WL (the word line WL of the lowest layer in FIG. 3) placed furthest in the −Z direction are connected to the word line WL (the fourth word line WL from the bottom) shifted by three layers in the +Z direction from the word line WL placed furthest in the −Z direction. The contact 70 adjacent in the −Y direction to the contact 70 connected to the fourth word line WL from the bottom are connected to the word line WL (the fifth word line WL from the bottom) shifted by one layer in the +Z direction. The contact 70 adjacent in the −Y direction to the contact 70 connected to the fifth word line WL from the bottom are connected to the word line WL (the sixth word line WL from the bottom) shifted by one layer in the +Z direction.

Hereinafter, the same applies to the contacts in the third and subsequent rows.

In the “three-column contact”, as also illustrated in FIG. 8, the word lines WL (conductive layers 41) connected to contacts adjacent to each other in the −X direction are shifted by three layers in the +Z direction.

The number (the number of contacts in the Y direction) of columns of contacts in the connection region IR is not limited, and may be, for example, four columns, two columns, or one column. When the number of columns of contacts in the connection region IR is, for example, 2, the word lines WL (conductive layers 41) connected to contacts adjacent to each contact in the −X direction are shifted by two layers in the +Z direction.

As illustrated in FIG. 9, the contact 70 includes a first spacer 71, a second spacer 72, and a metal film 73 sequentially from an outer periphery side. The first spacer is an example of a “first insulating film”. The second spacer is an example of a “second insulating film”.

The first spacer 71 is formed in, for example, an annular shape and extends in the Z direction. For example, the first spacer 71 extends over the entire length of the contact 70 in the Z direction. The first spacer 71 is formed of a film including, for example, silicon and oxygen. A film thickness t5 of the first spacer 71 is, for example, 15 nm to 35 nm.

An end portion of the first spacer 71 in the +Z direction, that is, a first end portion 71a on an opposite side to the semiconductor substrate 21 protrudes into the inside of a first conductive layer 41a in the Z direction among the plurality of conductive layers 41. That is, the first end portion 71a of the first spacer 71 is located inside the first conductive layer 41a.

The second spacer 72 is provided on an inner periphery side of the first spacer 71. An end portion of the second spacer 72 in the +Z direction, that is, a second end portion 72a on the opposite side to the semiconductor substrate 21 is in contact with a surface of the first conductive layer 41a in the −Z direction. Here, a “surface of the first conductive layer 41a in the −Z direction” is a surface of the first conductive layer 41a on a second conductive layer 41b side when the conductive layer 41 adjacent to the first conductive layer 41a in the −Z direction is referred to as the second conductive layer 41b. The “surface of the first conductive layer 41a in the −Z direction” is an example of a “first surface”.

The second spacer 72 is formed in, for example, an annular shape and extends in the Z direction. The second spacer 71 is formed of, for example, a film including silicon and oxygen, or a film including silicon, oxygen, and carbon. A film thickness t6 of the second spacer 72 is preferably greater than the film thickness t5 of the first spacer 71. By making the film thickness t6 of the second spacer 72 sufficiently large, a breakdown voltage between the contact 70 and the conductive layer 41 can be ensured.

The metal film 73 is provided on an inner periphery side of the second spacer 72. The metal film 73 is formed of a conductive material such as tungsten. The metal film 73 is formed in, for example, a columnar shape and extends in the Z direction. The wire 83 is connected to an end portion of the metal film 73 on the −Z direction side.

A barrier metal film 74 is formed between the second spacer 72 and the metal film 73. The barrier metal film 74 is a layer that reduces diffusion of a material of the metal film 73. The barrier metal film 74 is formed of, for example, titanium nitride (TiN), titanium (Ti), tantalum (Ta), tantalum nitride (TaN), or tungsten nitride (WN). However, the barrier metal film 74 is not limited to the above example and may be formed of another material that can be expected to reduce diffusion of the material of the metal film 73.

Here, in the connection region IR of the present embodiment, the first conductive layer 41a surrounded by the first spacer 71 includes a protrusion 41aa protruding inside the first spacer 71 toward the −Z direction. The protrusion 41aa is in contact with the second end portion 72a of the second spacer 72 in the +Z direction, that is, on the opposite side of the semiconductor substrate 21, and an end portion of the barrier metal film 74 in the +Z direction, and a width W1 of the protrusion 41aa is greater than a width W2 of the metal film 73. In the example illustrated in FIG. 9, a part of the barrier metal film 74 extends into the protrusion 41aa, but the present embodiment is not limited thereto. For example, the end portion of the barrier metal film 74 in the +Z direction may be in contact with an end portion of the protrusion 41aa. The protrusion is formed in self-alignment with respect to the contact.

Here, in the contact 70 of the present embodiment, the second end portion 72a of the second spacer 72 is located to be closer to the −Z direction than the first end portion 71a of the first spacer 71. In other words, the distance t2 between the second end portion 72a of the second spacer 72 and a surface of the first conductive layer 41a on the +Z direction side is longer than the distance t1 between the first end portion 71a of the first spacer 71 and a surface of the first conductive layer 41a on the +Z direction side. That is, a film thickness of the first conductive layer 41a at a position corresponding to the second end portion 72a of the second spacer 72 is greater than a film thickness of the first conductive layer 41a at a position corresponding to the first end portion 71a of the first spacer 71. The “surface of the first conductive layer 41a on the +Z direction side” is a surface of the first conductive layer 41a on an opposite side to the second conductive layer 41b, and is an example of a “second surface”.

Further, the distance t2 between the second end portion 72a of the second spacer 72 and the surface of the first conductive layer 41a on the +Z direction side is greater than or equal to a thickness t3 of the first conductive layer 41a. Here, the distance t2 between the second end portion 72a of the second spacer 72 and the surface of the first conductive layer 41a on the +Z direction side corresponds to a thickness of the protrusion 41aa in the Z direction. That is, in the present embodiment, by forming the distance t2, which is the thickness of the protrusion 41aa formed by thickening the conductive layer 41 in a region where the contact 70 is formed, to be greater than or equal to the thickness t3 of the conductive layer 41 in a region other than the region where the contact 70 is formed, poor contact between the contact 70 and the conductive layer 41 can be further prevented. It is preferable that the distance t2 is greater than the thickness t3.

Further, the film thickness t5 of the first spacer 71 satisfies a condition in which a distance D1 between an intersection between an end surface of the protrusion 41aa on the second spacer 72 side and an inner surface of the first spacer 71 and an intersection between a surface of the second conductive layer 41b on the +Z direction side and an outer surface of the first spacer 71 is longer than a distance D2 between the first electrode layer 41a and a second electrode layer 42b. In this way, by making the film thickness t5 of the first spacer 71 sufficiently large, a breakdown voltage between the conductive layers 41 adjacent to each other in the Z direction can be further ensured. The “surface of the second conductive layer 41b on the +Z direction side” is a surface of the second conductive layer 41b on the first conductive layer 41a side, and is an example of a “third surface”.

### 7. Manufacturing Method

Next, a method of manufacturing the semiconductor memory device 1 will be described.

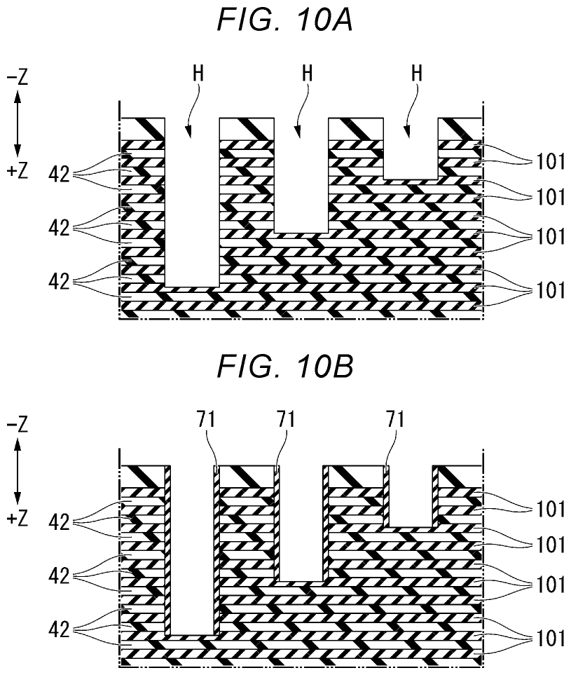

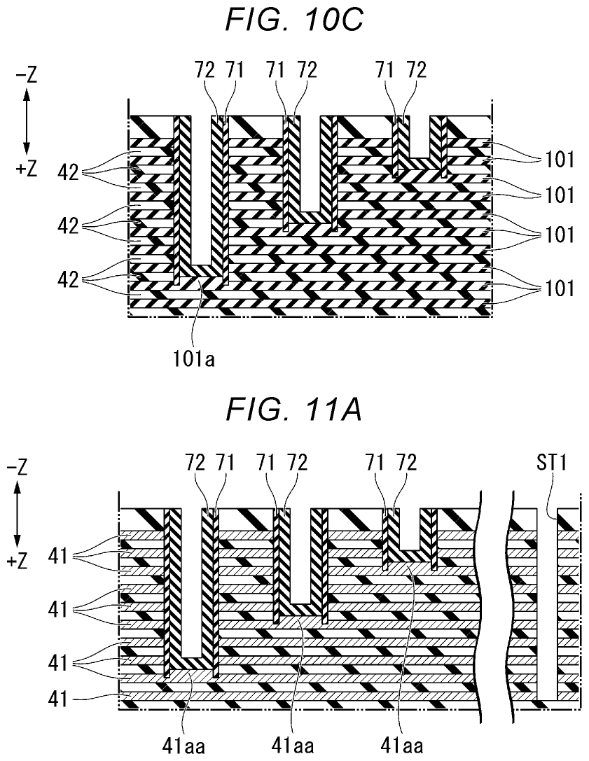

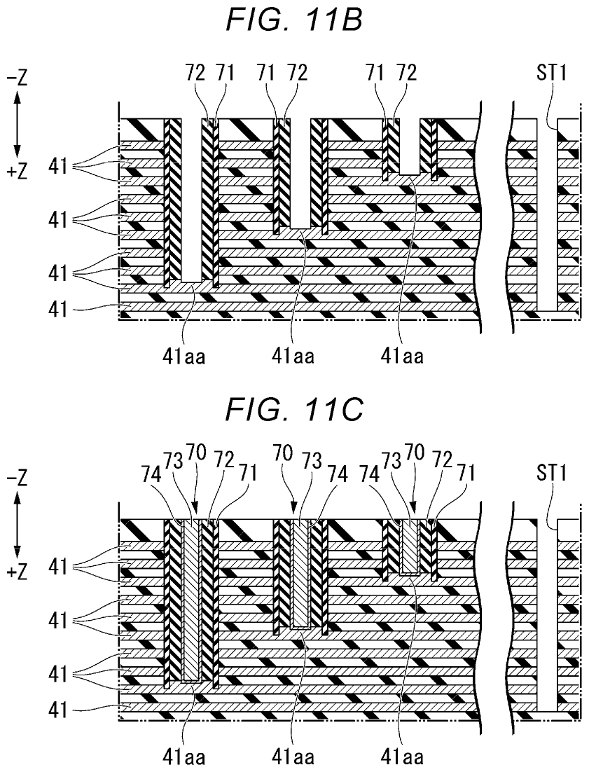

FIGS. 10A to 11C are cross-sectional views illustrating the method of manufacturing the semiconductor memory device 1. Hereinafter, a process related to forming the contact 70 in the connection region IR will be described. Hereinafter, a three-column staircase structure illustrated in FIG. 8 will be exemplified and described.

First, as illustrated in FIG. 10A, a stacked body 40A is formed by alternately stacking insulating layers 101 and insulating layers 42. The insulating layers 101 are sacrificial layers that are replaced with conductive layers 41 in a replacement process to be described below. The insulating layers 101 are formed of films each including, for example, silicon and nitrogen. Next, a plurality of grooves (or holes) H for providing contacts 70 are formed in the stacked body 40A. The grooves H adjacent to each other in the X direction are arranged every third row when viewed from the Y direction.

Here, as illustrated in FIG. 10A, a part of a surface of the insulating layer 101 exposed from a bottom surface of the groove H may be removed. That is, a thickness of the insulating layer 101 exposed at the bottom surface of the groove H may be thinner. When the replacement process to be described below is performed in such a state, the replaced conductive layer 41 is also thinner, and poor contact may occasionally occur between the sampling contact 70 and the conductive layer 41. Therefore, in the manufacturing method of the present embodiment, a thickness of the thinned insulating layer 101 is increased in a sacrificial film growth process to be described below. Details will be described below.

Next, the first spacer 71 is formed on a bottom surface and an inner wall of the groove H. By forming the first spacer on the inner wall of the groove H, an exposed surface of the insulating layer 101 is protected, and when the insulating layer 101 is replaced with the conductive layer 41 in the replacement process to be described below, the contact 70 can be protected.

Thereafter, as illustrated in FIG. 10B, the first spacer 71 corresponding to the bottom surface of the groove H is removed, and the first spacer 71 is provided on the inner wall of the groove H.

Next, as illustrated in FIG. 10C, the insulating layer 101 exposed from the bottom surface of the groove H is selectively grown to form a protrusion 101a (sacrificial film growth process).

Hereinafter, a preferable method for selectively growing the insulating layer 101 will be described.

First, Si is used as a vapor phase raw material (precursor), and the Si precursor is exposed on a surface of the insulating layer 101 exposed from the bottom surface of the groove H. By applying heat to the exposed insulating layer 101, the insulating layer 101 including silicon and nitrogen selectively grows in the Z direction, and thereby, the protrusion 101a is formed. The protrusion 101a of the present embodiment is formed by selectively growing the surface of the insulating layer 101 including silicon and nitrogen, and accordingly, a shape of the protrusion 101a is convex as illustrated in FIG. 10C.

After the protrusion 101a is formed, the second spacer 72 is formed on an inner wall of the first spacer 71 and an upper surface of the protrusion 101a, as illustrated in FIG. 10C. A material of the second spacer 72 may be the same as a material of the first spacer 71.

Next, as illustrated in FIG. 11A, a trench ST1 for a division portion ST is formed, and a replacement process is performed. That is, the insulating layer 101 including the protrusion 101a is removed through the trench ST1 by wet etching. Next, a material of the conductive layer 41 is supplied to a space from which the insulating layer 101 is removed, and the conductive layer 41 and the protrusion 41aa are formed.

Next, as illustrated in FIG. 11B, the second spacer 72 corresponding to the bottom surface of the groove H is removed, and a surface of the protrusion 41aa is exposed.

Next, as illustrated in FIG. 11C, each of a barrier metal layer 74 and the metal film 73 is formed in the groove H, and the contact 70 is formed. Thereafter, the wiring portion 80 is formed on a surface of the contact 70 on the −Z direction side, and thereby, the second chip 3 is completed. Then, a vertical direction of the second chip 3 is reversed, and the first chip 2 and the second chip 3 are bonded together, and thereby, the semiconductor memory device 1 is formed.

Several embodiments are described above. The embodiments are not limited to the examples described above. For example, the number of strings STR (that is, the number of strings STR provided in one block BLK) disposed between two adjacent division portions ST is not limited to four, but may be three or less, or five or more.

According to at least one embodiment described above, in a semiconductor memory device, the distance t2 between a second end portion of a second insulating film and a surface of a first electrode layer on a +Z direction side is longer than the distance t1 between a first end portion of a first insulating film and the surface of the first electrode layer on the +Z direction side. That is, a film thickness of a first electrode layer at a position corresponding to the second end portion of the second insulating film is greater than a film thickness of a first electrode layer at a position corresponding to the first end portion of the first insulating film. According to such a configuration, poor contact between a contact and an electrode layer can be avoided, and a semiconductor memory device with excellent electrical characteristics can be obtained.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a substrate;
a stacked body provided above the substrate and including a plurality of electrode layers and a plurality of insulating layers alternately stacked in a first direction;
a plurality of columnar bodies extending into the stacked body in the first direction; and
a contact electrically coupled to a first electrode layer of the plurality of electrode layers, extending in the first direction, and passing through one or more second electrode layers of the plurality of electrode layers, the first electrode layer including a first surface and a second surface opposite to each other, the first surface disposed farther away from the one or more second electrode layers than the second surface in the first direction,
wherein the contact includes a first insulating film, a second insulating film, and a metal film all extending in the first direction, and wherein the first insulating film, the second insulating film, and the metal film are sequentially arranged from an outer side of the contact towards an inner side of the contact,
a first end portion of the first insulating film protrudes into the first electrode layer through the second surface in the first direction,
a second end portion of the second insulating film is in contact with a second surface of the first electrode layer, and
a distance t1 between the first end portion of the first insulating film and the first surface of the first electrode layer is shorter than a distance t2 between the second end portion of the second insulating film and the first surface of the first electrode layer.

2. The semiconductor memory device according to claim 1, wherein the distance t2 between the second end portion of the second insulating film and the first surface of the first electrode layer is greater than or equal to a thickness t3 of a portion of the first electrode layer that is interposed between adjacent ones of the insulating layers.

3. The semiconductor memory device according to claim 1, wherein the first electrode layer includes a protrusion protruding toward the second end portion of the second insulating film, and a width of the protrusion is greater than a width of the metal film.

4. The semiconductor memory device according to claim 3, wherein the protrusion is self-aligned with the contact.

5. The semiconductor memory device according to claim 3, wherein a film thickness of the first insulating film is determined based on a condition in which a distance D1 between a first intersection of an end surface of the protrusion and an inner surface of the first insulating film and a second intersection of a third surface of the second electrode layer and an outer surface of the first insulating film is longer than a distance D2 between the first electrode layer and the second electrode layer.

6. The semiconductor memory device according to claim 1, wherein a film thickness of the second insulating film is greater than a film thickness of the first insulating film.

7. The semiconductor memory device according to claim 1, wherein the contact further includes a barrier metal film extending along a sidewall and a bottom surface of the metal film.

8. The semiconductor memory device according to claim 7, wherein a portion of the barrier metal film extending along the sidewall of the metal film is interposed between the metal film and the second insulating film.

9. The semiconductor memory device according to claim 1, wherein the columnar bodies each include a memory film, a channel layer, an insulating core, and a cap portion.

10. The semiconductor memory device according to claim 1, wherein the columnar bodies are laterally spaced from the contact.

11. A semiconductor memory device comprising:
a substrate;
a stacked body provided above the substrate and including a plurality of electrode layers and a plurality of insulating layers alternately stacked in a first direction; and
a plurality of contacts electrically coupled to a first electrode layer among the plurality of electrode layers, extending in the first direction, and passing through one or more other second electrode layers of the plurality of electrode layers disposed over the first electrode layer;
wherein the contact includes a first insulating film, a second insulating film, and a metal film, each of which extends in the first direction, and wherein the metal film, the second insulating film, and the first insulating film are radially arranged from an inner side to an outside of the contact,
the first insulating film has a first end portion protruding into the first electrode layer through a top surface of the first electrode layer in the first direction,
the second insulating film has a second end portion in contact with at least a portion of the top surface.

12. The semiconductor memory device according to claim 11, wherein the first end portion of the first insulating film is formed closer to a bottom surface of the first electrode layer than the second end portion of the second insulating film.

13. The semiconductor memory device according to claim 11, further comprising a plurality of columnar bodies extending into the stacked body in the first direction.

14. The semiconductor memory device according to claim 13, wherein the columnar bodies are laterally spaced from the contact.

15. The semiconductor memory device according to claim 13, wherein the columnar bodies each include a memory film, a channel layer, an insulating core, and a cap portion.

16. A method, comprising:
forming a stacked body provided above a substrate, wherein the stacked body includes a plurality of insulating layers and a plurality of sacrificial insulating layers alternately stacked in a vertical direction;
forming a first hole extending into the stacked body to expose a first one of the sacrificial insulating layers;
forming a first spacer extending along an inner sidewall of the first hole with the first sacrificial insulating layer exposed;
growing a protrusion selectively from the first sacrificial insulating layer;
forming a second spacer over the protrusion and along an inner sidewall of the first spacer;
replacing the sacrificial insulating layers with a plurality of electrode layers, respectively; and
filling the first hole with at least one metal material to form a first contact for a first one of the plurality of electrode layers that replaces the first sacrificial insulating layer.

17. The method according to claim 16, further comprising:
forming a second hole extending into the stacked body to expose a second one of the sacrificial insulating layers, wherein the second sacrificial insulating layer is disposed below or above the first sacrificial insulating layer in the vertical direction;
forming the first spacer extending along an inner sidewall of the second hole with the second sacrificial insulating layer exposed;
growing another protrusion selectively from the second sacrificial insulating layer;
forming the second spacer over the another protrusion and along another inner sidewall of the second spacer; and
filling the second hole with the at least one metal material to form a second contact for a second one of the plurality of electrode layers that replaces the second sacrificial insulating layer.

18. The method according to claim 17, wherein the first contact and the second contact have different heights.
